(19) United States
(12) Patent Application Publication
(10) Pub. No.: US 2024/0379907 A1
(43) Pub. Date: Nov. 14, 2024

(54) GROUP III ELEMENT NITRIDE SEMICONDUCTOR SUBSTRATE AND BONDED SUBSTRATE

(71) Applicant: NGK INSULATORS, LTD., Nagoya-shi (JP)

(72) Inventors: Ayumi SAITO, Nagoya-shi (JP); Tomohiko SUGIYAMA, Nagoya-shi (JP)

(21) Appl. No.: 18/779,193

(22) Filed: Jul. 22, 2024

Related U.S. Application Data
(63) Continuation of application No. PCT/JP2023/001180, filed on Jan. 17, 2023.

(30) Foreign Application Priority Data
Mar. 14, 2022 (JP) 2022-039050

(51) Int. Cl. H01L 33/32; H01L 33/22

(52) U.S. Cl. CPC H01L 33/32; H01L 33/22

(57) ABSTRACT

A Group-III element nitride semiconductor substrate includes: a first surface; and a second surface. When a range from an outer periphery of a surface of the first surface to a portion distant therefrom by 1 mm is defined as an outer peripheral portion, and a portion of the surface of the first surface except the outer peripheral portion is defined as an inner peripheral portion, the outer peripheral portion and the inner peripheral portion are continuous to each other on a boundary therebetween so as to be flush with each other, and an altered layer is observed in the outer peripheral portion and the altered layer is free from being observed in the inner peripheral portion by cathode luminescence observation.

### CROSS-REFERENCE TO RELATED APPLICATIONS

This application is a continuation under 35 U.S.C. 120 of International Application PCT/JP2023/001180 having the International Filing Date of 17 Jan. 2023 and having the benefit of the earlier filing date of Japanese Application No. 2022-039050, filed on 14 Mar. 2022. Each of the identified applications is fully incorporated herein by reference.

### BACKGROUND OF THE INVENTION

### 1. Field of the Invention

The present invention relates to a Group-III element nitride semiconductor substrate. More specifically, the present invention relates to a Group-III element nitride semiconductor substrate including a main surface and a back surface in a front and back relationship, the Group-III element nitride semiconductor substrate being suppressed from causing a scratch in its surface.

### 2. Description of the Related Art

A Group-III element nitride semiconductor substrate, such as a gallium nitride (GaN) wafer, an aluminum nitride (AlN) wafer, or an indium nitride (InN) wafer, has been used as each of the substrates of various semiconductor devices (e.g., Patent Literature 1).

A semiconductor substrate includes a first surface and a second surface. When the first surface is defined as a main surface, and the second surface is defined as a back surface, the main surface is typically a Group-III element polar surface, and the back surface is typically a nitrogen polar surface. An epitaxial crystal may be grown on the main surface, and various devices may be produced thereon.

The Group-III element nitride semiconductor substrate has been used as a base substrate of a semiconductor device, such as an LED or an LD.

Wide-gap semiconductors headed by a gallium nitride substrate have been expected to find applications as next-generation power devices that bring technological innovation in terms of various aspects, such as an increase in withstand voltage, a reduction in loss, an increase in switching speed, and device downsizing.

The gallium nitride substrate has a problem in that its production cost is high because a failure, such as a scratch or cracking (a crack, a fracture, or a chip), is liable to occur in its production process owing to its high hardness, and hence its yield reduces.

As a technology for an improvement in yield in the production of the gallium nitride substrate, the following technology has been reported (Patent Literature 2): an inclined surface having an angle of from 70° to 130° from the front surface side of the substrate is formed on the outer peripheral surface of the substrate to suppress the occurrence of a crack, to thereby reduce a crack yield.

However, the technology reported in Patent Literature 2 has a problem in that an increase in cost due to the addition of a process called outer periphery processing is inevitable in the production of the gallium nitride substrate because the outer shape of the substrate needs to be precisely processed into a special shape with a specific outer shape processing machine.

In addition, in the gallium nitride substrate, not only cracking but also a scratch occurring in its surface causes a reduction in performance of a device to be produced thereon. However, the technology reported in Patent Literature 2 is not a technology intended to solve the occurrence of such scratch.

### CITATION LIST

### Patent Literature

[PTL 1] JP 2005-263609 A
[PTL 2] JP 2011-211046 A

### SUMMARY OF THE INVENTION

An object of the present invention is to provide a Group-III element nitride semiconductor substrate including a first surface and a second surface, the Group-III element nitride semiconductor substrate being suppressed from causing a scratch in its surface.

[1] A Group-III element nitride semiconductor substrate according to an embodiment of the present invention includes: a first surface; and a second surface. When a range from an outer periphery of a surface of the first surface to a portion distant therefrom by 1 mm is defined as an outer peripheral portion, and a portion of the surface of the first surface except the outer peripheral portion is defined as an inner peripheral portion, the outer peripheral portion and the inner peripheral portion are continuous to each other on a boundary therebetween so as to be flush with each other, and an altered layer is observed in the outer peripheral portion and the altered layer is free from being observed in the inner peripheral portion by cathode luminescence observation.

[2] In the above-mentioned item [1], at least one kind selected from the following (A) and (B) is observed by the cathode luminescence observation:
(A) 10 or more blind scratches are present in the outer peripheral portion; and
(B) a ratio of the altered layer in the outer peripheral portion is 5% or more.

[3] In the above-mentioned item [1] or [2], the substrate has a diameter of 45 mm or more.

[4] According to another aspect of the present invention, there is provided a bonded substrate. The bonded substrate includes: the Group-III element nitride semiconductor substrate of any one of the above-mentioned items [1] to [3]; and a support substrate bonded thereto.

According to the embodiment of the present invention, the Group-III element nitride semiconductor substrate including the first surface and the second surface, the Group-III element nitride semiconductor substrate being suppressed from causing a scratch in its surface can be provided.

### BRIEF DESCRIPTION OF THE DRAWINGS

FIG. 1 is a typical schematic sectional view of a Group-III element nitride semiconductor substrate according to an embodiment of the present invention.

FIG. 2 is a schematic plan view for describing an outer peripheral portion and an inner peripheral portion in the Group-III element nitride semiconductor substrate according to the embodiment of the present invention.

FIG. 3 is a schematic plan view for describing line segments L1 to L6 on an image obtained by the cathode luminescence observation of the Group-III element nitride semiconductor substrate.

FIG. 4 is a photograph taken by the cathode luminescence observation of the outer peripheral portion of a gallium nitride substrate obtained in Comparative Example 1.

FIG. 5 is a photograph taken by the cathode luminescence observation of the outer peripheral portion of a gallium nitride substrate obtained in Example 1.

### DESCRIPTION OF THE EMBODIMENTS

When the expression “weight” is used herein, the expression may be replaced with “mass” that is commonly used as an SI unit representing a weight.

A Group-III element nitride semiconductor substrate according to an embodiment of the present invention is typically a freestanding substrate formed of a Group-III element nitride crystal. In this description, the term “freestanding substrate” means a substrate that is not deformed or broken by its own weight at the time of its handling, and hence can be handled as a solid. The freestanding substrate may be used as each of the substrates of various semiconductor devices, such as a light-emitting device and a power-controlling device.

The Group-III element nitride semiconductor substrate according to the embodiment of the present invention typically has a wafer shape (substantially complete round shape). However, the substrate may be processed into any other shape such as a rectangular shape as required.

Any appropriate size may be adopted as the size (diameter) of the Group-III element nitride semiconductor substrate according to the embodiment of the present invention to the extent that an effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches). The size (diameter) of the Group-III element nitride semiconductor substrate according to the embodiment of the present invention is preferably 45 mm or more, more preferably 50 mm or more.

The thickness of the Group-III element nitride semiconductor substrate according to the embodiment of the present invention (when the thickness is not constant, the thickness of a site having the largest thickness) is 200 μm or more, preferably from 300 μm to 1,000 μm.

Typical examples of the Group-III element nitride include gallium nitride (GaN), aluminum nitride (AlN), indium nitride (InN), and a mixed crystal thereof. Those nitrides may be used alone or in combination thereof.

The Group-III element nitride is specifically GaN, AlN, InN, GaₓAl₁₋ₓN (1>x>0), GaₓIn₁₋ₓN (1>x>0), AlₓIn₁₋ₓN (1>x>0), or GaₓAl_{y}In_{z}N (1>x>0, 1>y>0, x+y+z=1). Those nitrides may be doped with various n-type dopants or p-type dopants.

Typical examples of the p-type dopants include zinc (Zn), manganese (Mn), Iron (Fe), beryllium (Be), magnesium (Mg), strontium (Sr), and cadmium (Cd). Those dopants may be used alone or in combination thereof.

Typical examples of the n-type dopants include silicon (Si), germanium (Ge), tin (Sn), and oxygen (O). Those dopants may be used alone or in combination thereof.

The plane direction of the Group-III element nitride semiconductor substrate may be set to any one of a c-plane, an m-plane, an a-plane, and a specific crystal plane tilted from each of the c-plane, the a-plane, and the m-plane, and particularly when the plane direction is set to the c-plane, the effect exhibited by the embodiment of the present invention can be further expressed. Examples of the specific crystal plane tilted from each of the c-plane, the a-plane, and the m-plane may include so-called semipolar planes, such as a {11-22} plane and a {20-21} plane. In addition, the plane direction is permitted to include not only a so-called just plane vertical to the c-plane, the a-plane, the m-plane, or the specific crystal plane tilted from each of the planes but also an off-angle in the range of +5°.

The Group-III element nitride semiconductor substrate according to the embodiment of the present invention is a Group-III element nitride semiconductor substrate including a first surface and a second surface. When the first surface is defined as a main surface, and the second surface is defined as a back surface, as long as the plane direction of the Group-III element nitride semiconductor substrate is the c-plane, the main surface is typically a Group-III element polar surface, and the back surface is typically a nitrogen polar surface. However, the main surface may be set to the nitrogen polar surface, and the back surface may be set to the Group-III element polar surface. An epitaxial crystal may be grown on the main surface, and various devices may be produced thereon. The back surface may be held with a susceptor or the like to transfer the Group-III element nitride semiconductor substrate according to the embodiment of the present invention.

In the description of the Group-III element nitride semiconductor substrate according to the embodiment of the present invention, the first surface is described as the main surface, and the second surface is described as the back surface. Accordingly, in this description, the term “main surface” may be replaced with “first surface,” the term “first surface” may be replaced with “main surface,” the term “back surface” may be replaced with “second surface,” and the term “second surface” may be replaced with “back surface.”

The main surface may be a mirror surface or a non-mirror surface. The main surface is preferably a mirror surface.

The back surface may be a mirror surface or a non-mirror surface.

The term “mirror surface” refers to a surface subjected to mirror processing, the surface being brought into a state in which the roughness and waviness of the surface are reduced to such an extent that light is reflected after the mirror processing, and hence the fact that an object is reflected on the surface subjected to the mirror processing can be visually observed. In other words, the term refers to a surface in a state in which the magnitude of each of the roughness and waviness of the surface after the mirror processing is reduced to such an extent as to be sufficiently negligible with respect to the wavelength of visible light. An epitaxial crystal can be sufficiently grown on the surface subjected to the mirror processing.

Any appropriate method may be adopted as a method for the mirror processing to the extent that the effect exhibited by the embodiment of the present invention is not impaired. An example of such method is a method including performing the mirror processing through use of one, or a combination of two or more, of the following apparatus: a polishing apparatus using a tape; a lapping apparatus using diamond abrasive grains; and a chemical mechanical polishing (CMP) apparatus using a slurry such as colloidal silica and a polishing pad made of a nonwoven fabric.

The term “non-mirror surface” refers to a surface that is not subjected to mirror processing, and a typical example thereof is a rough surface obtained by surface-roughening treatment.

Any appropriate method may be adopted as a method for the surface-roughening treatment to the extent that the effect exhibited by the embodiment of the present invention is not impaired. Examples of such method include: grinding with an abrasive stone; laser texture processing; etching treatment with various chemical liquids and gases; physical or chemical coating treatment; and texturing by machining.

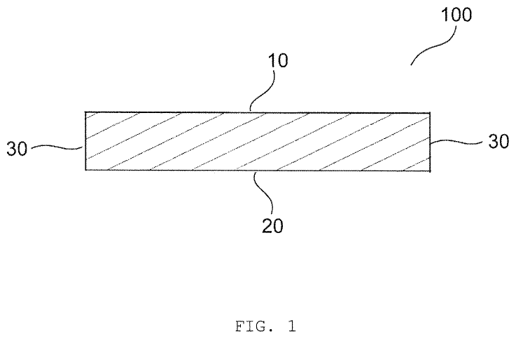

FIG. 1 is a typical schematic sectional view of the Group-III element nitride semiconductor substrate according to the embodiment of the present invention. As illustrated in FIG. 1, a Group-III element nitride semiconductor substrate 100 according to the embodiment of the present invention typically has a main surface (Group-III element polar surface) 10 and a back surface (nitrogen polar surface) 20. The Group-III element nitride semiconductor substrate 100 according to the embodiment of the present invention may have a side surface 30.

An end portion of the Group-III element nitride semiconductor substrate according to the embodiment of the present invention may adopt any appropriate form to the extent that the effect exhibited by the embodiment of the present invention is not impaired. Examples of the shape of the end portion of the Group-III element nitride semiconductor substrate according to the embodiment of the present invention include: a shape in which a main surface side and a back surface side are each chamfered so as to be a flat surface; a shape in which the main surface side and the back surface side are each chamfered in an R-shape; a shape in which only the main surface side of the end portion is chamfered so as to be a flat surface; and a shape in which only the back surface side of the end portion is chamfered so as to be a flat surface.

When the end portion of the Group-III element nitride semiconductor substrate according to the embodiment of the present invention is chamfered, the chamfered portion may be arranged over the entire circumference of an outer peripheral portion, or may be arranged only in part of the outer peripheral portion.

When a range from the outer periphery of the surface of the first surface of the Group-III element nitride semiconductor substrate according to the embodiment of the present invention to a portion distant therefrom by 1 mm is defined as an outer peripheral portion, and the portion of the surface of the first surface except the outer peripheral portion is defined as an inner peripheral portion, an altered layer is observed in the outer peripheral portion and no altered layer is observed in the inner peripheral portion by cathode luminescence observation.

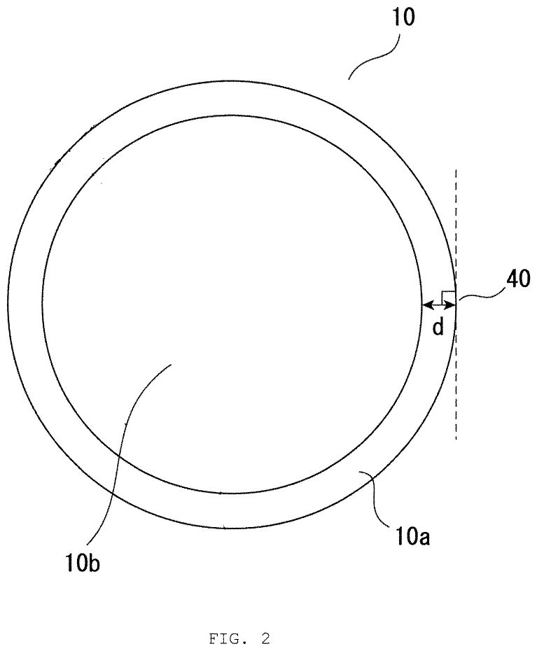

FIG. 2 is a schematic plan view for describing the outer peripheral portion and the inner peripheral portion in the Group-III element nitride semiconductor substrate according to the embodiment of the present invention. FIG. 2 is an illustration of the Group-III element nitride semiconductor substrate according to the embodiment of the present invention when viewed from its main surface (first surface) direction. An outer peripheral portion 10a is a region from an outer peripheral end portion 40 to a portion distant therefrom by a width “d” (=1 mm) toward the inside of a main surface 10 over the entire circumference of the substrate. The width “d” (=1 mm) is a distance starting from the outer peripheral end portion 40, and is a distance in a normal direction toward the inside of the main surface 10 with respect to a tangent at the outer peripheral end portion 40. The width “d” (=1 mm) is constant in the entirety of the main surface 10. An inner peripheral portion 10b is a region in the main surface 10 except the outer peripheral portion 10a. When the outer periphery of the substrate is chamfered, the above-mentioned outer peripheral end portion means the end portion of the substrate including the chamfered portion.

In the Group-III element nitride semiconductor substrate according to the embodiment of the present invention, the altered layer is observed in the outer peripheral portion and no altered layer is observed in the inner peripheral portion by the cathode luminescence observation. That is, the Group-III element nitride semiconductor substrate according to the embodiment of the present invention is designed so that the altered layer may be present in the outer peripheral portion, and no altered layer may be present in the inner peripheral portion. When the altered layer is present in the outer peripheral portion, and no altered layer is present in the inner peripheral portion as described above, the effect exhibited by the embodiment of the present invention can be expressed.

The cathode luminescence observation is typically performed by using a scanning electron microscope (SEM) with a cathode luminescence detector.

The inventors of the present invention have conceived that a conventional cause for the occurrence of a scratch in the surface of a gallium nitride substrate is as follows: the surface is shaved by a fine gallium nitride crystal, which has occurred near the outer periphery of the substrate or has entered unevenness near the outer periphery of the substrate. Then, the inventors have conceived that as the extent to which the vicinity of the outer periphery of the substrate warps in a concave shape becomes larger, the fine gallium nitride crystal, which has occurred near the outer periphery of the substrate or has entered the unevenness near the outer periphery of the substrate, more easily moves onto the surface of the substrate. The inventors have assumed that when the concave-shaped warping near the outer periphery of the substrate can be suppressed, the fine gallium nitride crystal hardly moves to the surface, and as a result, the occurrence of the scratch in the surface of the gallium nitride substrate can be suppressed. In view of the foregoing, the inventors have investigated technical means by which the concave-shaped warping near the outer periphery of the substrate can be suppressed, and as a result, have assumed that when the altered layer is caused to be present near the outer periphery of the substrate, a force that warps the vicinity in a convex shape is produced near the outer periphery of the substrate by a Twyman effect, and hence the concave-shaped warping near the outer periphery of the substrate can be suppressed. Thus, the inventors have made an investigation, and as a result, have found that when the altered layer is caused to be present in the outer peripheral portion of the substrate, and no altered layer is caused to be present in the inner peripheral portion of the substrate, the occurrence of the scratch in the surface of the gallium nitride substrate can be effectively suppressed.

In the embodiment of the present invention, even when the altered layer is present in the outer peripheral portion as described above, no problem occurs at the time of practical use because the outer peripheral portion is set as the region ranging from the outer periphery to the portion distant therefrom by 1 mm as described above, and no device is typically produced on such narrow region in the end portion of the substrate.

The appearance of the altered layer in the cathode luminescence observation typically varies depending on a factor for the occurrence thereof. For example, an altered layer caused by a scratch is observed as a black straight line in the cathode luminescence observation. An altered layer caused by a factor other than the scratch (e.g., heat or a pressure) is observed as a black region having a certain area in the cathode luminescence observation.

As described above, the presence of the altered layer in the outer peripheral portion can be grasped by at least one kind selected from the following facts when the cathode luminescence observation is performed: (a) the layer is observed as a black straight line (typically, an altered layer caused by a scratch); and (b) the layer is observed as a black region having a certain area (typically, an altered layer caused by a factor other than the scratch (e.g., heat or a pressure)).

The above-mentioned (a) is preferably observed as the below-indicated (A) because the effect exhibited by the embodiment of the present invention can be further expressed: (A) 10 or more blind scratches are present in the outer peripheral portion.

The above-mentioned (b) is preferably observed as the below-indicated (B) because the effect exhibited by the embodiment of the present invention can be further expressed: (B) the ratio of the altered layer in the outer peripheral portion is 5% or more.

That is, in the Group-III element nitride semiconductor substrate according to the embodiment of the present invention, at least one kind selected from the below-indicated (A) and (B) is preferably observed by the cathode luminescence observation because the effect exhibited by the embodiment of the present invention can be further expressed:
(A) 10 or more blind scratches are present in the outer peripheral portion; and
(B) the ratio of the altered layer in the outer peripheral portion is 5% or more.

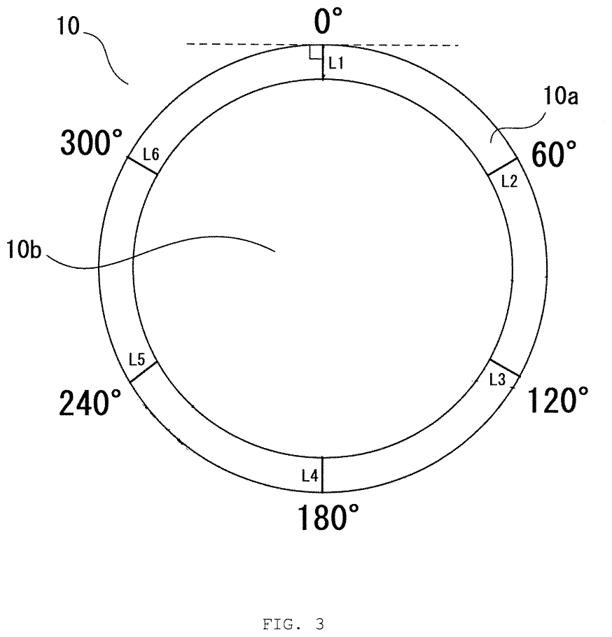

In the embodiment of the present invention, the above-mentioned (A) or (B) is typically determined as described below. FIG. 3 is an illustration of the Group-III element nitride semiconductor substrate when viewed from its main surface (first surface) direction. As illustrated in FIG. 3, when the uppermost end of the main surface 10 of the Group-III element nitride semiconductor substrate serving as a measurement object is defined as 0°, 1-millimeter line segments L1 to L6 are drawn from 6 outer peripheral points arranged every 60°, that is, at) 0° (=360°, 60°, 120°, 180°, 240°, and 300° toward the center of the substrate. Those line segments L1 to L6 are drawn toward the center of the substrate by drawing line segments so that the line segments may be perpendicular to tangents to the respective outer peripheral points. In the embodiment of the present invention, the range from the outer periphery of the surface of the first surface to the portion distant therefrom by 1 mm is defined as the outer peripheral portion, and the portion of the surface of the first surface except the outer peripheral portion is defined as the inner peripheral portion. Accordingly, as illustrated in FIG. 3, the endpoint of each of the line segments L1 to L6 opposite to the corresponding outer peripheral point is positioned on a boundary between the outer peripheral portion 10a and the inner peripheral portion 10b. With regard to the above-mentioned (A), the number of the points of intersection of each of the line segments L1 to L6 with blind scratches is counted, and when the average of the counted numbers is 10 or more, it is judged that 10 or more blind scratches are present in the outer peripheral portion. With regard to the above-mentioned (B), the sum of the distances of a low-brightness region through which the respective line segments L1 to L6 pass is measured, and when the average of the total distance is 50 μm or more, it is judged that the ratio of the altered layer in the outer peripheral portion is 5% or more.

The above-mentioned low-brightness region refers to a region having a brightness of from 0% to 10% when the maximum brightness of an image obtained by the cathode luminescence observation of the measurement object is defined as 100%, and the brightness of an image obtained by the cathode luminescence observation of a carbon tape under the same conditions as those of the cathode luminescence observation of the measurement object is defined as 0%. Even a sample other than the above-mentioned carbon tape may be used as a reference sample to be used at the time of the setting of a brightness of 0% as long as no brightness signal appears in the sample. The brightness of the flat portion of the reference sample to be used at the time of the setting of a brightness of 0% is measured as in typical measurement conditions because when the sample is brought into a pointed state by, for example, bending, a brightness signal appears owing to an unexpected edge effect.

Meanwhile, the fact that no altered layer is observed in the inner peripheral portion is typically determined as described below. The entirety of a region measuring 500 μm by 500 μm at the center of the Group-III element nitride semiconductor substrate serving as the measurement object is subjected to cathode luminescence observation. When the number of blind scratches observed in an image to be obtained is 5 or less, and the area ratio of a low-brightness region observed in the image to be obtained is 1% or less, it is judged that no altered layer is observed in the inner peripheral portion. The cathode luminescence observation of the inner peripheral portion described above is performed under the same conditions as those of the cathode luminescence observation of the outer peripheral portion.

The Group-III element nitride semiconductor substrate according to the embodiment of the present invention may be produced by any appropriate method to the extent that the effect exhibited by the embodiment of the present invention is not impaired. A method of producing the Group-III element nitride semiconductor substrate according to the embodiment of the present invention, which is preferred because the effect exhibited by the embodiment of the present invention can be further expressed, is described below.

In the method of producing the Group-III element nitride semiconductor substrate according to the embodiment of the present invention, typically, a seed crystal film is formed on the main surface of a base substrate, and a Group-III element nitride layer is formed on the Group-III element polar surface of the seed crystal film. Next, a Group-III element nitride layer (seed crystal film+Group-III element nitride layer) serving as a freestanding substrate is separated from the base substrate. Thus, a freestanding substrate having a main surface and a back surface is obtained.

Any appropriate material may be adopted as a material for the base substrate to the extent that the effect exhibited by the embodiment of the present invention is not impaired. Examples of such material include sapphire, crystal oriented alumina, gallium oxide, AlₓGa₁₋ₓN (0≤x≤1), GaAs, and SiC.

Any appropriate material may be adopted as a material for the seed crystal film to the extent that the effect exhibited by the embodiment of the present invention is not impaired. Examples of such material include AlₓGa₁₋ₓN (0≤x≤1) and InₓGa₁₋ₓN (0≤x≤1). Of those, gallium nitride is preferred.

Any appropriate formation method may be adopted as a method of forming the seed crystal film to the extent that the effect exhibited by the embodiment of the present invention is not impaired. Such formation method is, for example, a vapor growth method, and preferred examples thereof include a metal-organic chemical vapor deposition (MOCVD) method, a hydride vapor phase epitaxy (HVPE) method, a pulsed excitation deposition (PXD) method, a molecular beam epitaxy (MBE) method, and a sublimation method. Of those, a MOCVD method is more preferred as the method of forming the seed crystal film.

The formation of the seed crystal film by the MOCVD method is preferably performed by, for example, depositing a low-temperature grown buffer layer by from 20 nm to 50 nm at from 450° C. to 550° C., and then laminating a film having a thickness of from 2 μm to 4 μm at from 1,000° C. to 1,200° C.

Any appropriate growth direction may be adopted as the growth direction of the Group-III element nitride crystal layer to the extent that the effect exhibited by the embodiment of the present invention is not impaired. Examples of such growth direction include: the normal direction of the c-plane of a wurtzite structure; the normal direction of each of the a-plane and m-plane thereof; and the normal direction of a plane tilted from each of the c-plane, the a-plane, and the m-plane.

Any appropriate formation method may be adopted as a method of forming the Group-III element nitride crystal layer to the extent that the effect exhibited by the embodiment of the present invention is not impaired as long as a layer to be formed by the method has a crystal direction substantially following the crystal direction of the seed crystal film. Examples of such formation method include: gas phase growth methods, such as a MOCVD method, a HVPE method, a PXD method, a MBE method, and a sublimation method; liquid phase growth methods, such as a Na flux method, an ammonothermal method, a hydrothermal method, and a sol-gel method; a powder growth method utilizing solid phase growth of powder; and a combination thereof.

When the Na flux method is adopted as the method of forming the Group-III element nitride crystal layer, the Na flux method is preferably performed in conformity with a production method described in JP 5244628 B2 by appropriately adjusting the conditions and the like so that the effect exhibited by the embodiment of the present invention can be further expressed.

The formation of the Group-III element nitride crystal layer by the Na flux method is typically preferably performed as follows: a seed crystal substrate (base substrate+seed crystal film) is arranged in a crucible serving as a growing container under a nitrogen atmosphere; a melt composition containing a Group-III element, metal Na, and as required, a dopant (e.g., an n-type dopant, such as germanium (Ge), silicon (Si), or oxygen (O); or a p-type dopant, such as beryllium (Be), magnesium (Mg), calcium (Ca), strontium (Sr), zinc (Zn), or cadmium (Cd)) is further loaded into the crucible; the crucible is lidded; the lidded crucible is loaded into an external container; the external container is further loaded into a pressure-resistant container; and under a nitrogen atmosphere, after the temperature and pressure of the container are increased, the container is rotated while the temperature and the pressure are retained.

Next, the freestanding substrate including the Group-III element nitride crystal layer may be obtained by separating the Group-III element nitride crystal layer from the base substrate.

Any appropriate method may be adopted as a method of separating the Group-III element nitride crystal layer from the base substrate to the extent that the effect exhibited by the embodiment of the present invention is not impaired. Examples of such method include: a method including causing the Group-III element nitride crystal layer to spontaneously separate from the base substrate through use of a thermal shrinkage difference in a temperature decrease step after the growth of the Group-III element nitride crystal layer; a method including separating the Group-III element nitride crystal layer from the base substrate through chemical etching; a method including separating the Group-III element nitride crystal layer from the base substrate by a laser lift-off method including applying laser light from the back surface side of the base substrate; and a method including separating the Group-III element nitride crystal layer from the base substrate through grinding. In addition, the freestanding substrate including the Group-III element nitride crystal layer may be obtained by slicing the Group-III element nitride crystal layer through utilization of a wire saw or the like.

In the Group-III element nitride crystal layer thus obtained by the Na flux method, it is preferred that a plate surface thereof be flattened by being ground with an abrasive stone or the like, and the plate surface be then smoothened, for example, by being lapped with diamond abrasive grains.

Next, the freestanding substrate is shaped into a circular shape having a desired diameter by grinding its outer peripheral portion.

Any appropriate size may be adopted as the size of the freestanding substrate to the extent that the effect exhibited by the embodiment of the present invention is not impaired. Such size is, for example, 25 mm (about 1 inch), from 45 mm to 55 mm (about 2 inches), from 95 mm to 105 mm (about 4 inches), from 145 mm to 155 mm (about 6 inches), from 195 mm to 205 mm (about 8 inches), or from 295 mm to 305 mm (about 12 inches).

Next, the main surface and/or the back surface is subjected to removal processing by surface processing, such as grinding, lapping, or polishing, so that the substrate may be thinned and flattened to a desired thickness. Thus, a freestanding substrate is obtained.

At the time of the performance of surface processing, such as grinding, lapping, or polishing, the freestanding substrate is typically bonded to a processing surface plate by, for example, using a wax. At this time, the pressure at which the freestanding substrate is bonded to the processing surface plate, specifically, a pressure to be applied to the freestanding substrate when the freestanding substrate is bonded to the processing surface plate is appropriately adjusted.

The thickness of the freestanding substrate after the polishing (when the thickness is not constant, the thickness of a place having the largest thickness) is preferably 200 μm or more, more preferably from 300 μm to 1,000 μm.

The outer peripheral edge of the freestanding substrate is chamfered through grinding as required.

In the Group-III element nitride semiconductor substrate according to the embodiment of the present invention, the chamfering may be performed by any appropriate chamfering method to the extent that the effect exhibited by the embodiment of the present invention is not impaired. Examples of such chamfering method include: grinding with a diamond abrasive stone; polishing with a tape; and chemical mechanical polishing (CMP) using a slurry such as colloidal silica and a polishing pad made of a nonwoven fabric.

When an altered layer remains on the surface of each of the main surface and the back surface after its processing, the altered layer is generally removed. A method of removing the altered layer is, for example, a method including removing the altered layer through use of reactive ion etching (RIE) or a chemical liquid, or a method including annealing the substrate. In particular, the main surface is generally preferably a surface from which an altered layer that may be formed after its surface processing such as mirror processing is substantially removed, and in which surface roughness in a microscopic region is small from the viewpoint of obtaining the following semiconductor devices: the devices, which are produced by epitaxially growing device layers, have satisfactory characteristics, and variations in device characteristics between the devices are small. However, in the embodiment of the present invention, an altered layer that may be formed in the outer peripheral portion of the main surface after its surface processing such as mirror processing is preferably caused to remain because when the altered layer is caused to be present in the outer peripheral portion of the main surface, there can be provided such a Group-III element nitride semiconductor substrate that the occurrence of a scratch in its surface is suppressed.

Any appropriate method may be adopted as a method of causing the altered layer to remain in the outer peripheral portion of the main surface to the extent that the effect exhibited by the embodiment of the present invention is not impaired. One preferred embodiment of the method of causing the altered layer to remain in the outer peripheral portion of the main surface is, for example, as follows because the effect exhibited by the embodiment of the present invention can be further expressed: RIE is performed while conditions are adjusted so that the altered layer may remain in the outer peripheral portion of the main surface. According to the RIE, an altered layer formed by a scratch, heat, or a pressure at the time of the processing of the sample can be removed because plasma can be generated to cause an ion or a radical to collide with the sample, to thereby shave its surface by an amount as small as several micrometers. The amount of the shaving by the RIE may be changed by adjusting conditions for the RIE. In addition, the RIE can be performed only on one surface per time. Accordingly, the RIE is performed on the Group-III element nitride semiconductor substrate twice because the RIE is typically performed on both of its main surface and back surface. Accordingly, conditions for the RIE on the main surface and those for the RIE on the back surface can be separately adjusted, and hence the amount of the main surface to be shaved by the RIE and the amount of the back surface to be shaved by the RIE can be made different from each other. Herein, the thickness (depth) of the altered layer tends to be deeper in the vicinity of the outer periphery of the substrate than in the vicinity of the center thereof. In view of the foregoing, the RIE is performed on each of the main surface and the back surface as follows: with regard to the RIE on the main surface, the conditions for the RIE are set so that the altered layer in its outer peripheral portion may not be completely shaved; and with regard to the RIE on the back surface, the conditions therefor are set so that the altered layer on its entire surface including its outer peripheral portion may be shaved off. Thus, a state in which the altered layer is present in the outer peripheral portion of the main surface and no altered layer is present in the inner peripheral portion of the main surface can be established.

The appearance of the altered layer in its cathode luminescence observation typically varies depending on the kind of an abrasive stone to be used at the time of the performance of surface processing, such as grinding, lapping, or polishing. In a freestanding substrate immediately after its surface processing, an altered layer caused by a scratch and an altered layer caused by heat or a pressure are generally mixed. Accordingly, for example, when RIE is performed under such conditions that the altered layer only in the inner peripheral portion of the substrate can be removed and the altered layer in the outer peripheral portion thereof is not completely shaved, which one of the altered layer caused by a scratch or the altered layer caused by heat or a pressure more easily remains after the performance of the RIE varies depending on the depth of a blind scratch. In general, when the surface processing is performed with abrasive grains that have higher dispersibility, more hardly aggregate, and have smaller particle diameter, the blind scratch becomes shallower, and hence the altered layer caused by heat or a pressure becomes deeper than the other altered layer. Accordingly, when the RIE is performed under such conditions that the altered layer only in the inner peripheral portion can be removed and the altered layer in the outer peripheral portion is not completely shaved, the altered layer caused by heat or a pressure remains after the RIE, and as a result, the altered layer is observed as a low-brightness region. Meanwhile, when the surface processing is performed with abrasive grains that have lower dispersibility, more easily aggregate, and have larger particle diameter, the blind scratch becomes deeper, and hence the altered layer caused by heat or a pressure becomes shallower than the other altered layer. Accordingly, when the RIE is performed under such conditions that the altered layer only in the inner peripheral portion can be removed and the altered layer in the outer peripheral portion is not completely shaved, the blind scratch remains after the RIE, and as a result, the altered layer is observed as the blind scratch.

A crystal can be epitaxially grown on the main surface (Group-III element polar surface) of the Group-III element nitride semiconductor substrate to be obtained, and the formation of a functional layer can provide a functional device.

The epitaxial crystal to be grown on the Group-III element nitride semiconductor substrate to be obtained may be, for example, gallium nitride, aluminum nitride, indium nitride, or a mixed crystal thereof. Specific examples of such epitaxial crystal include GaN, AlN, InN, GaₓAl₁₋ₓN (1>x>0), GaₓIn₁₋ₓN (1>x>0), AlₓIn₁₋ₓN (1>x>0), and GaₓAl_{y}In_{z}N (1>x>0, 1>y>0, x+y+z=1). In addition, examples of the functional layer to be arranged on the Group-III element nitride semiconductor substrate to be obtained include a rectifying device layer, a switching device layer, and a power semiconductor layer in addition to a light-emitting layer. In addition, the thickness and thickness distribution of the freestanding substrate may be reduced by subjecting the nitrogen polar surface to processing, such as grinding or polishing, after the arrangement of the functional layer on the Group-III element polar surface of the Group-III element nitride semiconductor substrate to be obtained.

A bonded substrate according to an embodiment of the present invention may be obtained by bonding the Group-III element nitride semiconductor substrate to be obtained and a support substrate to each other. That is, the bonded substrate according to the embodiment of the present invention is obtained by bonding the Group-III element nitride semiconductor substrate according to the embodiment of the present invention and the support substrate to each other.

The bonded substrate according to the embodiment of the present invention may further include any appropriate layer to the extent that the effect exhibited by the embodiment of the present invention is not impaired. The kinds, functions, number, combination, arrangement, and the like of such layers may be appropriately determined in accordance with purposes.

Any appropriate thickness may be adopted as the thickness of the support substrate to the extent that the effect exhibited by the embodiment of the present invention is not impaired. The thickness of the support substrate is, for example, from 100 μm to 1,000 μm.

Any appropriate substrate may be used as the support substrate to the extent that the effect exhibited by the embodiment of the present invention is not impaired. The support substrate may include a monocrystalline body, or may include a polycrystalline body.

In the bonded substrate according to the embodiment of the present invention, for example, the joint surface of the Group-III element nitride semiconductor substrate and the joint surface of the support substrate are directly joined to each other. Specifically, the bonded substrate according to the embodiment of the present invention is obtained, for example, as follows: the joint surface of the support substrate and the joint surface of the Group-III element nitride semiconductor substrate are caused to face each other; and the joint surface of the support substrate and the joint surface of the Group-III element nitride semiconductor substrate are subjected to surface activation, and are then joined to each other. After that, a desired epitaxial film may be formed on the film formation surface of the Group-III element nitride semiconductor substrate.

In the bonded substrate according to the embodiment of the present invention, for example, a joining layer may be arranged between the Group-III element nitride semiconductor substrate and the support substrate. Specifically, the bonded substrate according to the embodiment of the present invention is obtained, for example, as follows: the joint surface of the joining layer on the main surface of the support substrate and the joint surface of the Group-III element nitride semiconductor substrate are caused to face each other; and the joint surface of the joining layer and the joint surface of the Group-III element nitride semiconductor substrate are subjected to surface activation, and are then joined to each other. After that, a desired epitaxial film may be formed on the film formation surface of the Group-III element nitride semiconductor substrate. The following may be performed: the joining layer is arranged on the main surface of the Group-III element nitride semiconductor substrate, and the joint surface of the joining layer is directly joined to the joint surface of the support substrate. Alternatively, the following may be performed: a first joining layer is arranged on the main surface of the Group-III element nitride semiconductor substrate, a second joining layer is arranged on the main surface of the support substrate, and the joint surface of the first joining layer is directly joined to the joint surface of the second joining layer.

When the bonded substrate according to the embodiment of the present invention is an embodiment in which the joining layer is arranged between the Group-III element nitride semiconductor substrate and the support substrate, the joining layer is preferably at least one kind selected from the group consisting of: tantalum pentoxide; alumina; aluminum nitride; silicon carbide; sialon; and Si₍₁₋ₓ₎Oₓ (0.008≤x≤0.408). Thus, a joining strength between the support substrate and the Group-III element nitride semiconductor substrate can be further improved.

Sialon is a ceramic obtained by sintering a mixture of silicon nitride and alumina, and has the following composition.

Si_{6-z}Al_{z}O_{z}N_{8-z}

That is, sialon has such composition that alumina is mixed in silicon nitride, and “z” represents the mixing ratio of alumina. “z” more preferably represents 0.5 or more. “z” more preferably represents 4.0 or less.

### Examples

The present invention is specifically described below by way of Examples. However, the present invention is by no means limited to Examples. Test and evaluation methods in Examples and the like are as described below. The term “part(s)” in the following description means “part(s) by weight” unless otherwise specified, and the term “%” in the following description means “wt %” unless otherwise specified.

### <Conditions for Cathode Luminescence Observation>

A scanning electron microscope (SEM) with a cathode luminescence detector was used in cathode luminescence observation. Specifically, the observation was performed with a scanning electron microscope S-3400N (manufactured by Hitachi High-Technologies Corporation) with Mini Cathode Luminescence System (manufactured by Gatan, Inc.) at an acceleration voltage of 15 kV, a probe current of “95”, a working distance (W.D.) of 15 mm, and a magnification of 100 under a state in which the cathode luminescence detector was inserted between a sample and an objective lens. When dirt is present in the sample, there is a risk in that the dirt is observed black in an image obtained in the cathode luminescence observation, and is hence regarded as a low-brightness region. Accordingly, a clean sample free of any dirt was used as the sample.

### <Observation of Low-Brightness Region by Cathode Luminescence Observation>

For a low-brightness region, when the maximum brightness of an image obtained by the cathode luminescence observation of a measurement object was defined as 100%, and the brightness of an image obtained by the cathode luminescence observation of a carbon tape under the same conditions as those of the cathode luminescence observation of the measurement object was defined as 0%, a region having a brightness of from 0% to 10% was defined as the low-brightness region.

### <Observation of Presence of Altered Layer in Outer Peripheral Portion by Cathode Luminescence Observation>

The presence of an altered layer in an outer peripheral portion was observed by the following method. As illustrated in FIG. 3, when the uppermost end of the main surface 10 of a Group-III element nitride semiconductor substrate serving as a measurement object was defined as 0°, 1-millimeter line segments L1 to L6 were drawn from 6 outer peripheral points arranged every 60°, that is, at) 0° (=360°, 60°, 120°, 180°, 240°, and 300° toward the center of the substrate. Those line segments L1 to L6 were drawn toward the center of the substrate by drawing line segments so that the line segments were perpendicular to tangents to the respective outer peripheral points. A range from the outer periphery of the surface of a first surface to a portion distant therefrom by 1 mm is defined as an outer peripheral portion, and the portion of the surface of the first surface except the outer peripheral portion is defined as an inner peripheral portion. Accordingly, as illustrated in FIG. 3, the endpoint of each of the line segments L1 to L6 opposite to the corresponding outer peripheral point is positioned on a boundary between the outer peripheral portion 10a and the inner peripheral portion 10b. The number of the points of intersection of each of the line segments L1 to L6 with blind scratches was counted, and when the average of the counted numbers was 10 or more, it was judged that 10 or more blind scratches were present in the outer peripheral portion. The sum of the distances of a low-brightness region through which the respective line segments L1 to L6 passed was measured, and when the average of the total distance was 50 μm or more, it was judged that the ratio of the altered layer in the outer peripheral portion was 5% or more.

### <Observation of Absence of Altered Layer in Inner Peripheral Portion by Cathode Luminescence Observation>

The absence of an altered layer in the inner peripheral portion was observed by the following method. A region measuring 500 μm by 500 μm at the center of the Group-III element nitride semiconductor substrate serving as the measurement object was subjected to cathode luminescence observation under the same conditions as those of the cathode luminescence observation of the outer peripheral portion. When the number of blind scratches observed in an image to be obtained was 5 or less, and the area ratio of a low-brightness region observed in the image to be obtained was 1% or less, it was judged that no altered layer was observed in the inner peripheral portion.

<Method of counting Scratches in Main Surface of Produced Group-III Element Nitride Semiconductor Substrate>

The produced Group-III element nitride semiconductor substrate was used as a sample, and the number of scratches in its main surface was measured with an optical surface analyzer Candela CS20V. While the sample was rotated, laser light of a standard linear polarization mode having a wavelength of 405 nm was applied thereto, and unevenness on the surface of the sample detected from reflected light with a position-sensitive photodetector was output as an image. Scratches present 2 mm or more inside the edge of the produced Group-III element nitride semiconductor substrate were counted from the resultant image.

### Comparative Example 1

A gallium nitride crystal was grown on a sapphire substrate serving as a base substrate. After the growth, the base substrate and the GaN crystal were separated from each other with laser light. The separated gallium nitride crystal was ground and polished, and then an affected layer was removed by reactive ion etching (RIE). At this time, conditions were set so that altered layers on both the main surface and back surface of the crystal were able to be sufficiently removed. Washing and an inspection were performed after the RIE. Thus, a gallium nitride substrate having a diameter of 50.8 mm was obtained as a finished product.

The number of blind scratches in a range (outer peripheral portion) from the edge of the main surface of the gallium nitride substrate serving as the finished product to a portion distant therefrom by 1 mm was less than 10.

Scratches present in a region except a range from the edge of the main surface of the gallium nitride substrate thus produced to a portion distant therefrom by 2 mm were counted. The scratch counting was performed on 25 gallium nitride substrates. As a result, the average of the scratches in the main surfaces of the substrates was 28.

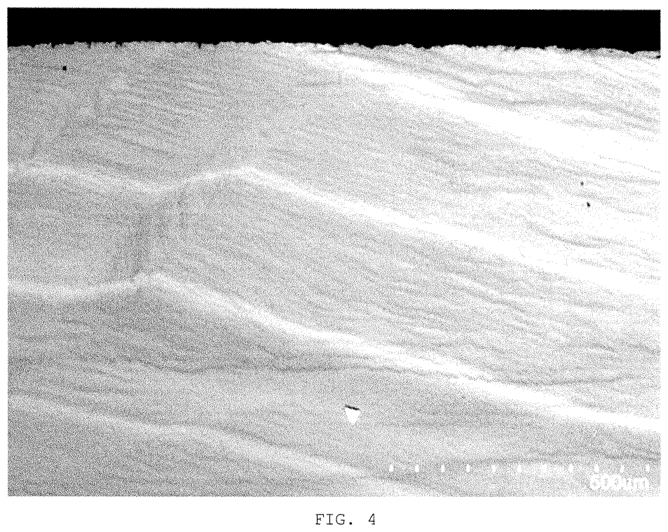

A photograph taken by the cathode luminescence observation of the outer peripheral portion is shown in FIG. 4.

### Example 1

A gallium nitride crystal was grown on a sapphire substrate serving as a base substrate. After the growth, the base substrate and the gallium nitride crystal were separated from each other with laser light. The separated gallium nitride crystal was ground and polished, and then an affected layer was removed by reactive ion etching (RIE). At this time, conditions were set so that a large amount of an altered layer remained near the outer periphery of the main surface of the crystal.

With regard to the back surface thereof, conditions were set so that an altered layer on its entirety was able to be sufficiently removed. Washing and an inspection were performed after the RIE. Thus, a gallium nitride substrate having a diameter of 50.8 mm was obtained as a finished product.

Ten or more blind scratches were present in a range (outer peripheral portion) from the edge of the main surface of the gallium nitride substrate serving as the finished product to a portion distant therefrom by 1 mm. In addition, no altered layer was observed in the inner peripheral portion of the main surface of the gallium nitride substrate serving as the finished product.

Scratches present in a region except a range from the edge of the main surface of the gallium nitride substrate thus produced to a portion distant therefrom by 2 mm were counted. The scratch counting was performed on 25 gallium nitride substrates. As a result, the average of the scratches in the main surfaces of the substrates was 9.

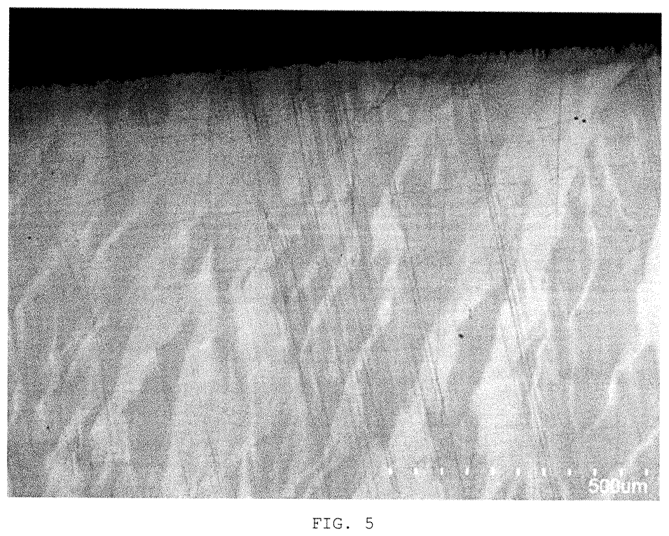

A photograph taken by the cathode luminescence observation of the outer peripheral portion is shown in FIG. 5.

### Comparative Example 2

A gallium nitride crystal was grown on a sapphire substrate serving as a base substrate. After the growth, the base substrate and the gallium nitride crystal were separated from each other with laser light. The separated gallium nitride crystal was ground and polished, and then an altered layer was removed by reactive ion etching (RIE). At this time, conditions were set so that altered layers on both the main surface and back surface of the crystal were able to be sufficiently removed. Washing and an inspection were performed after the RIE. Thus, a gallium nitride substrate having a diameter of 50.8 mm was obtained as a finished product.

The ratio of the altered layer in a range (outer peripheral portion) from the edge of the main surface of the gallium nitride substrate serving as the finished product to a portion distant therefrom by 1 mm was less than 5%.

Scratches present in a region except a range from the edge of the main surface of the gallium nitride substrate thus produced to a portion distant therefrom by 2 mm were counted. The scratch counting was performed on 25 gallium nitride substrates. As a result, the average of the scratches in the main surfaces of the substrates was 26.

### Example 2

A gallium nitride crystal was grown on a sapphire substrate serving as a base substrate. After the growth, the base substrate and the gallium nitride crystal were separated from each other with laser light. The separated gallium nitride crystal was ground and polished, and then an altered layer was removed by reactive ion etching (RIE). At this time, conditions were set so that a large amount of an altered layer remained near the outer periphery of the main surface of the crystal. With regard to the back surface thereof, conditions were set so that an altered layer on its entirety was able to be sufficiently removed. Washing and an inspection were performed after the RIE. Thus, a gallium nitride substrate having a diameter of 50.8 mm was obtained as a finished product.

The ratio of the altered layer in a range (outer peripheral portion) from the edge of the main surface of the gallium nitride substrate serving as the finished product to a portion distant therefrom by 1 mm was 5% or more. In addition, no altered layer was observed in the inner peripheral portion of the main surface of the gallium nitride substrate serving as the finished product.

Scratches present in a region except a range from the edge of the main surface of the gallium nitride substrate thus produced to a portion distant therefrom by 2 mm were counted. The scratch counting was performed on 25 gallium nitride substrates. As a result, the average of the scratches in the main surfaces of the substrates was 9.

The Group-III element nitride semiconductor substrate according to the embodiment of the present invention may be utilized as each of the substrates of various semiconductor devices.

What is claimed is:

1. A Group-III element nitride semiconductor substrate, comprising:
a first surface; and
a second surface,
wherein when a range from an outer periphery of a surface of the first surface to a portion distant therefrom by 1 mm is defined as an outer peripheral portion, and a portion of the surface of the first surface except the outer peripheral portion is defined as an inner peripheral portion, the outer peripheral portion and the inner peripheral portion are continuous to each other on a boundary therebetween so as to be flush with each other, and an altered layer is observed in the outer peripheral portion and the altered layer is free from being observed in the inner peripheral portion by cathode luminescence observation.

2. The Group-III element nitride semiconductor substrate according to claim 1, wherein at least one kind selected from the following (A) and (B) is observed by the cathode luminescence observation:
(A) 10 or more blind scratches are present in the outer peripheral portion; and
(B) a ratio of the altered layer in the outer peripheral portion is 5% or more.

3. The Group-III element nitride semiconductor substrate according to claim 1, wherein the substrate has a diameter of 45 mm or more.

4. A bonded substrate, comprising:
the Group-III element nitride semiconductor substrate of claim 1; and
a support substrate bonded thereto.

5. The Group-III element nitride semiconductor substrate according to claim 2, wherein the substrate has a diameter of 45 mm or more.

6. A bonded substrate, comprising:
the Group-III element nitride semiconductor substrate of claim 2; and
a support substrate bonded thereto.

7. A Group-III element nitride semiconductor substrate, comprising:
a first surface; and
a second surface,
wherein the substrate has a diameter of 45 mm or more,
wherein when a range from an outer periphery of a surface of the first surface to a portion distant therefrom by 1 mm is defined as an outer peripheral portion, and a portion of the surface of the first surface except the outer peripheral portion is defined as an inner peripheral portion, the outer peripheral portion and the inner peripheral portion are continuous to each other on a boundary therebetween so as to be flush with each other, and an altered layer is observed in the outer peripheral portion and the altered layer is free from being observed in the inner peripheral portion by cathode luminescence observation, and
wherein at least one kind selected from the following (A) and (B) is observed by the cathode luminescence observation:
(A) 10 or more blind scratches are present in the outer peripheral portion; and
(B) a ratio of the altered layer in the outer peripheral portion is 5% or more.
